(19) United States
(12) Patent Application Publication
(10) Pub. No.: US 2017/0250362 A1
(43) Pub. Date: Aug. 31, 2017

(54) DISPLAY DEVICE

(71) Applicant: Japan Display Inc., Minato-ku (JP)

(72) Inventor: Kenta HIRAGA, Minato-ku (JP)

(73) Assignee: Japan Display Inc., Minato-ku (JP)

(21) Appl. No.: 15/441,574

(22) Filed: Feb. 24, 2017

(30) Foreign Application Priority Data
Feb. 29, 2016 (JP) 2016-037311

(51) Int. Cl. H01L 51/50; H01L 27/32; H01L 51/52

(52) U.S. Cl. CPC H01L 51/5012; H01L 51/5203; H01L 27/3244

(57) ABSTRACT

A display device includes a plurality of pixel electrodes being separated from each other each of which has a flat portion on at least a part of an upper surface, a carrier injection/transport layer continuously stacked on the plurality of pixel electrodes, a plurality of light emitting layers stacked on the carrier injection/transport layer such that each of the light emitting layers is positioned directly above the plurality of pixel electrodes and a common electrode that is stacked so as to cover the plurality of light emitting layers. A surface of underlayer of the carrier injection/transport layer has an irregular shape including surfaces of the plurality of pixel electrodes, an upper surface of the carrier injection/transport layer is flat, and each of light emitting layers has a uniform thickness directly above at least the flat portion of the corresponding pixel electrode.

### CROSS-REFERENCE TO RELATED APPLICATION

The present application claims priority from Japanese application JP2016-037311 filed on Feb. 29, 2016, the content of which is hereby incorporated by reference into this application.

### BACKGROUND OF THE INVENTION

1. Field of the Invention

The present invention relates to a display device.

2. Description of the Related Art

In recent years, a display device using a self-luminous object such as an organic light emitting diode (OLED) has been put into practice. The display device using the self-luminous object such as an organic electro-luminescent (EL) display device using the OLED is superior in visibility and response speed as compared with a conventional liquid crystal display device. In addition, since the display device using the self-luminous object does not require auxiliary illumination such as a backlight, it is possible to further reduce a thickness of the display device.

JP 2011-249089 A discloses that in an organic EL display panel, an organic functional layer which is formed by a wet coating method and includes an organic light emitting layer is formed in an opening of an insulating film. JP 2014-123628 A discloses that in an organic EL display device, a contact hole may be filled with a high molecular material configuring a high molecular organic layer, and the high molecular organic layer may have a functions of a hole injection layer or a hole transport layer.

Unevenness occurs in a thickness of an organic light emitting layer in a case where the organic light emitting layer is formed with a coating type material in an opening which contains an opening of an insulating film or the like. When the unevenness occurs in the thickness of the organic light emitting layer, luminance of light emission is changed depending on a distance from a side wall of the opening, for example. Therefore, there are problems such as unevenness occurrence in light emission of an organic EL element.

### SUMMARY OF THE INVENTION

The present invention has been made in view of the above problems, and an object thereof is to provide a technique for reducing the problems of light emission caused by unevenness in a thickness of an organic light emitting layer.

Among the inventions disclosed in the present application, an outline of representative invention is briefly described as follows.

A display device according to the present invention includes a plurality of pixel electrodes being separated from each other with a clearance therebetween and each of which has a flat portion on at least a part of an upper surface, a carrier injection/transport layer which is continuously stacked on the plurality of pixel electrodes, a plurality of light emitting layers which are stacked on the carrier injection/transport layer such that each of the light emitting layers is positioned directly above the plurality of pixel electrodes, and a common electrode that is stacked so as to cover the plurality of light emitting layers. A surface of underlayer of the carrier injection/transport layer has an irregular shape including surfaces of the plurality of pixel electrodes, an upper surface of the carrier injection/transport layer is flat, and each of the light emitting layers has a uniform thickness directly above at least the flat portion of the corresponding pixel electrode.

According to the present invention, in the display device, problems of light emission caused by unevenness in a thickness of an organic light emitting layer can be reduced.

### BRIEF DESCRIPTION OF THE DRAWINGS

FIG. 1 is a perspective view illustrating an example of an organic EL display device according to a first embodiment.

FIG. 2 is a diagram illustrating a cross-section of an array substrate illustrated in FIG. 1.

FIG. 3A is a diagram illustrating a manufacturing process of the array substrate illustrated in FIG. 2.

FIG. 3B is a diagram illustrating the manufacturing process of the array substrate illustrated in FIG. 2.

FIG. 3C is a diagram illustrating the manufacturing process of the array substrate illustrated in FIG. 2.

FIG. 3D is a diagram illustrating the manufacturing process of the array substrate illustrated in FIG. 2.

FIG. 3E is a diagram illustrating the manufacturing process of the array substrate illustrated in FIG. 2.

FIG. 3F is a diagram illustrating the manufacturing process of the array substrate illustrated in FIG. 2.

FIG. 4 is a cross-sectional view illustrating a comparison example of the array substrate.

FIG. 5 is a cross-sectional view illustrating another example of the array substrate according to the embodiment of the present invention.

FIG. 6 is a cross-sectional view illustrating another example of the array substrate according to the embodiment of the present invention.

FIG. 7 is a cross-sectional view illustrating another example of the array substrate according to the embodiment of the present invention.

FIG. 8 is a cross-sectional view illustrating another example of the array substrate according to the embodiment of the present invention.

### DETAILED DESCRIPTION OF THE INVENTION

Hereinafter, embodiments of the present invention will be described based on drawings. The same composition elements having the same function are denoted with the same reference symbols, and a description thereof will be omitted. Furthermore, for ease of the description, embodiments illustrated in the drawings may be schematically represented as a width, a thickness, a shape, and the like of each part as compared with an actual aspect. However, it is merely an example, and it does not limit the interpretation of the present invention. Hereinafter, an organic electro luminescence (EL) display device using an organic light-emitting diode (OLED) will be described.

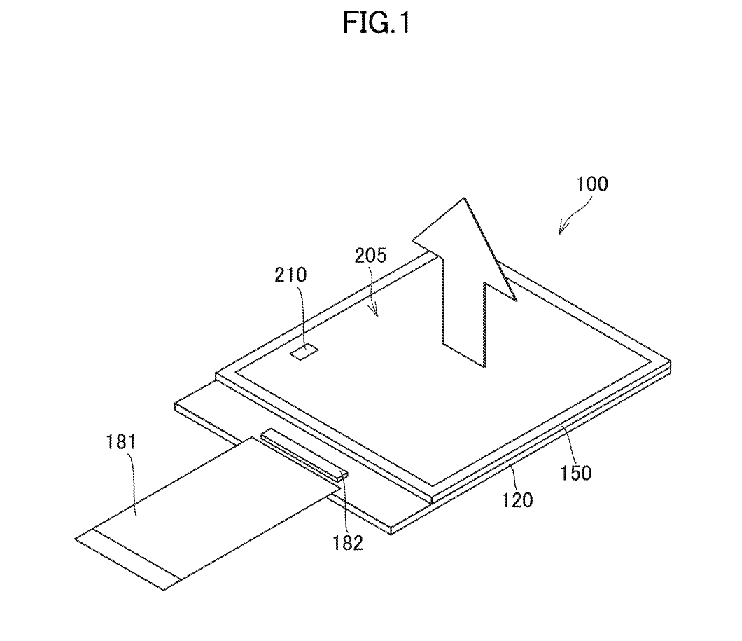

FIG. 1 is a perspective view illustrating an example of an organic EL display device 100 according to an embodiment of the present invention. As illustrated in FIG. 1, the organic EL display device 100 includes two substrates, an array substrate 120 and a counter substrate 150. The counter substrate 150 faces the array substrate 120.

The array substrate 120 or the counter substrate 150 is, for example, a substrate formed of an insulator such as a glass, and has an insulating surface. Pixel circuits are disposed on the array substrate 120 in a matrix. Each of the pixel circuits corresponds to pixels 210 and includes a thin film transistor (TFT). A drive integrated circuit 182 and a flexible printed circuit 181 for input an image signal or the like from the outside are attached to the array substrate 120. In the drive integrated circuit 182, a driving circuit that outputs a scanning signal for conduction between a source and a drain toward a pixel transistor included in each of the pixel circuits and outputs a signal corresponding to a display tone of the pixels 210 to a sub-pixel is provided. In addition, as illustrated by an arrow in the drawing, the organic EL display device 100 according to the present embodiment is a top emission organic EL display device that emits light to a side of the array substrate 120 on which a light emitting layer is formed.

A display region 205 formed of the pixels 210 disposed in a matrix is formed in the array substrate 120 and the counter substrate 150 of the organic EL display device 100. The pixels 210 arranged in a matrix pattern of x rows and y columns are disposed in the display region 205. Each of the pixels 210 outputs any color among 3 colors or 4 colors, and is also referred to as a sub-pixel. For example, a plurality of pixels 210 adjacent to each other and having different colors represent one point included in a displayed image.

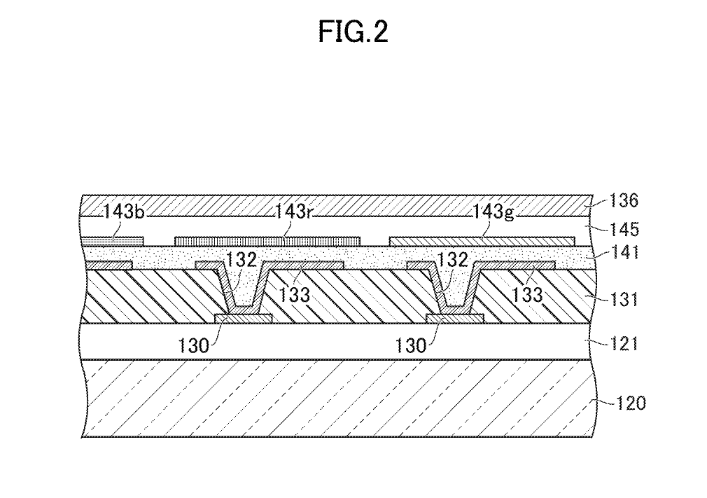

FIG. 2 is a diagram illustrating a cross-section of the array substrate 120 illustrated in FIG. 1. The cross-sectional view illustrated in FIG. 2 is a diagram of a cross-section crossing a red pixel 210, a green pixel 210, and a blue pixel 210 which are aligned in the display region 205 of the array substrate 120. Each of the pixels 210 includes one or more transistors and a wiring. In addition, one transistor that controls the luminance of an organic EL element by controlling a current following through the organic EL element or the like is provided on each of the pixels 210. A circuit layer 121 including the transistor and the wiring is formed on the array substrate 120. Each of the transistors includes a gate electrode, a source electrode, a drain electrode, and a channel formed of a semiconductor film. The circuit layer 121 includes, a semiconductor layer, an under gate insulating layer, a first electrode layer including the gate electrode, an upper gate insulating layer, and a second electrode layer including the source electrode and the drain electrode, in order from the bottom. A connection electrode 130 is disposed on the upper gate insulating layer. The connection electrode 130 is a part of the source electrode or the drain electrode included in the transistor for controlling the luminance and the connection electrode 130 is provided for connecting to a pixel electrode 133.

An interlayer insulating film 131 is formed on the circuit layer 121, and a plurality of contact holes 132 are formed in the interlayer insulating film 131. Here, one contact hole 132 is included in one pixel 210. At the bottom of the contact hole 132, the connection electrode 130 is exposed from the interlayer insulating film 131. A plurality of pixel electrodes 133 are provided on the interlayer insulating film 131. One pixel electrode 133 is included in one pixel 210. An inner side of a side wall of the contact hole 132, an upper surface of the bottom of the contact hole 132, and the upper surface of the interlayer insulating film 131 are in contact with the continuously extending pixel electrode 133. The pixel electrode 133 has a concave portion for electrically connecting to the connection electrode 130 inside the contact hole 132. The upper surface of the pixel electrode 133 has a concave portion inside the contact hole 132. At the bottom of the contact hole 132, a lower surface of the pixel electrode 133 is in contact with the upper surface of the connection electrode 130. The pixel electrode 133 included in a certain pixel 210 is separated from the adjacent pixel electrode 133 included in the adjacent pixel 210 with a clearance therebetween. In addition, at least apart of the upper surface of each of the pixel electrodes 133 has a flat portion, respectively. More specifically, a portion of the pixel electrode 133, the portion is on the upper surface of the interlayer insulating film 131, is flat. The side surface at the end portion of the pixel electrode 133 may be gently inclined (tapered shape). It is possible to prevent adverse influence due to electric field concentration on the end portion of the pixel electrode 133 by the tapered shaped.

A hole injection/transport layer 141 (first organic layer) is provided on the pixel electrode 133 so as to cover the pixel electrode 133. The hole injection/transport layer 141 includes a hole injection layer and a hole transport layer in order from the bottom. The hole injection/transport layer 141 covers the display region 205 as viewed in plan view. The hole injection/transport layer 141 is common to the plurality of pixels 210 in the display region 205, and is not divided for each pixel 210. The hole injection/transport layer 141 is in contact with the upper surface and the side surface of the pixel electrode 133 and a region on the upper surface of the interlayer insulating film 131 (an exposed surface of the interlayer insulating film 131 from the pixel electrode 133). The region is not covered with the plurality of pixel electrode 133. Irregular exists under the hole injection/transport layer 141 due to the concave portion of the pixel electrode 133 or the end portion of the pixel electrode 133, and the lower surface of the hole injection/transport layer 141 also corresponds to the irregular. On the other hand, the thickness of the hole injection/transport layer 141 is sufficient to cover the irregular, and the upper surface of the hole injection/transport layer 141 is flat. Specifically, the hole injection/transport layer 141 is provided so as to fill the concave portion of the pixel electrode 133 inside the contact holes 132.

Light emitting films 143r, 143g, and 143b are provided on the hole injection/transport layer 141. The light emitting films 143r, 143g, and 143b are included in the light emitting layer (second organic layer). A plurality of light emitting films 143r are provided so as to overlap with the pixel electrode 133 included in the red pixel 210 in plan view, a plurality of light emitting films 143g are provided so as to overlap with the pixel electrode 133 included in the green pixel 210 in plan view, and a plurality of light emitting films 143b are provided so as to overlap with the pixel electrode 133 included in the blue pixel 210 in plan view. In an example of FIG. 2, each of the light emitting films 143r, 143g, and 143b is provided separately from the other light emitting films. The red pixel 210 emits red light by the light emitting film 143r, the green pixel 210 emits green light by the light emitting film 143g, and the blue pixel 210 emits blue light by the light emitting film 143b. A plurality of light emitting films 143r, 143g, and 143b are grouped into a plurality of groups depending on the light emitting color.

A thickness of the plurality of light emitting films 143r, 143g, and 143b is uniform at least directly above the flat portion of the pixel electrode 133 corresponding to the light emitting film.

An electron injection/transport layer 145 (third organic layer) is stacked on the light emitting films 143r, 143g, and 143b. The electron injection/transport layer 145 includes an electron transport layer and an electron injection layer in order from the bottom. The electron injection/transport layer 145 covers the display region 205 in plan view. The electron injection/transport layer 145 is common to the plurality of pixels 210 in the display region 205, and is not separated for each pixel 210.

The electron injection/transport layer 145 is a layer in which electrons move as a carrier. On the other hand, the hole injection/transport layer 141 is a layer in which holes move as a carrier. Since the electron injection/transport layer 145 and the hole injection/transport layer 141 are common in terms of movement of the carrier for following the current, the electron injection/transport layer 145 and the hole injection/transport layer 141 are collectively referred to as a carrier injection/transport layer.

A common electrode 136 is provided on the electron injection/transport layer 145 so as to cover the electron injection/transport layer 145. The common electrode 136 is in contact with the upper surface of the electron injection/transport layer 145. The pixel electrode 133, the hole injection/transport layer 141, the light emitting films 143r, 143g, and 143b, the electron injection/transport layer 145, and the common electrode 136 configure an organic light emitting diode. In an example of FIG. 2, the pixel electrode 133 is an anode and the common electrode 136 is a cathode. Here, the pixel electrode 133 may be the cathode, and the common electrode 136 may be the anode. In this case, the electron injection layer, the electron transport layer, the light emitting layer, the hole transport layer, and the hole injection layer may be sequentially stacked on the pixel electrode 133. The plurality of organic light emitting diodes and the plurality of pixels 210 in the display region 205 are grouped into a group depending on the emitting color.

Although not illustrated in the drawings, a sealing film is stacked on the common electrode 136. In addition, the sealing film is adhered to the counter substrate 150 through a filler.

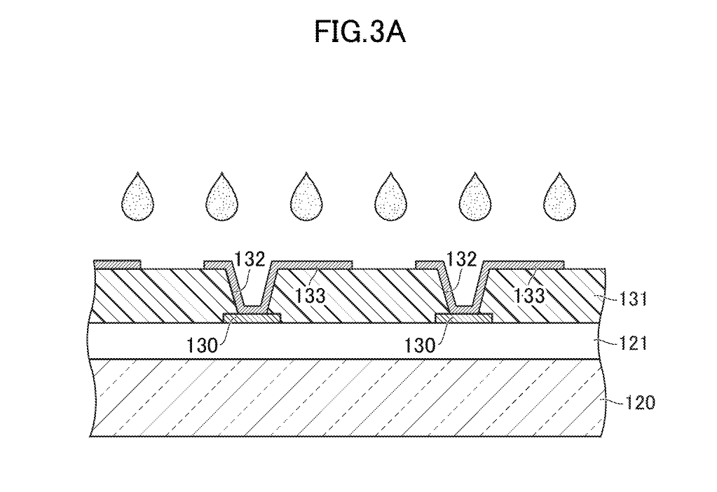

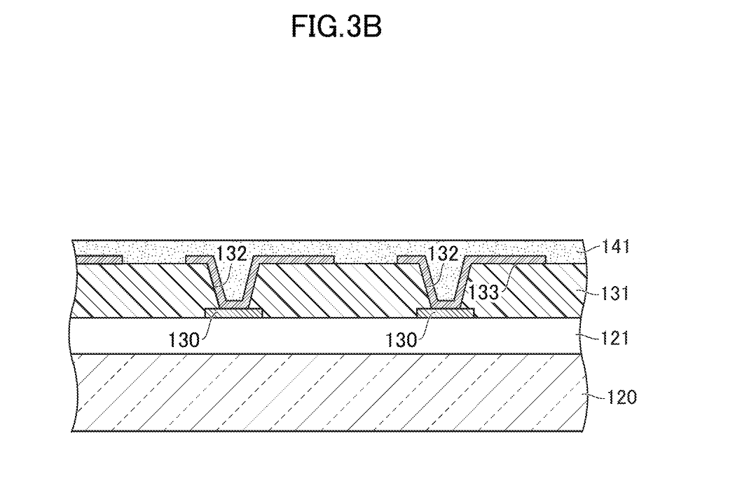

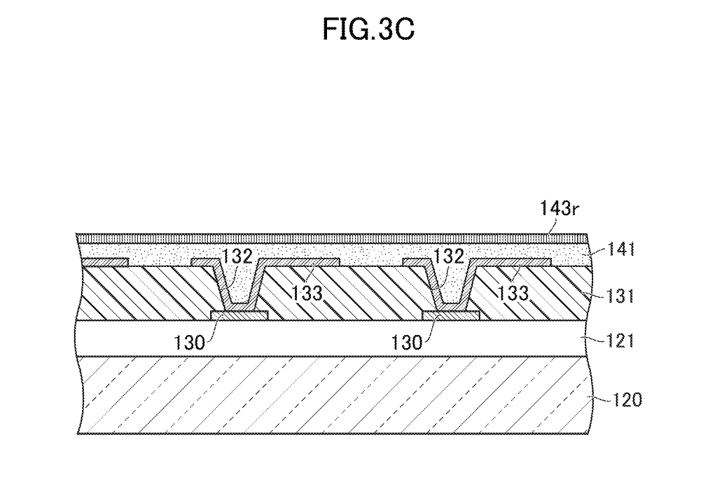

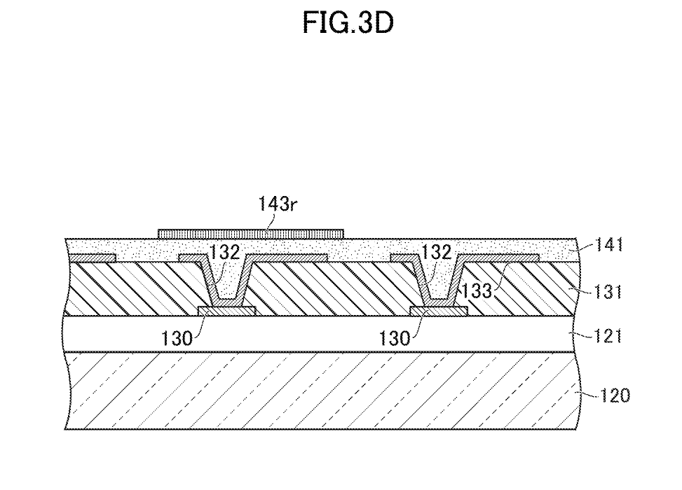

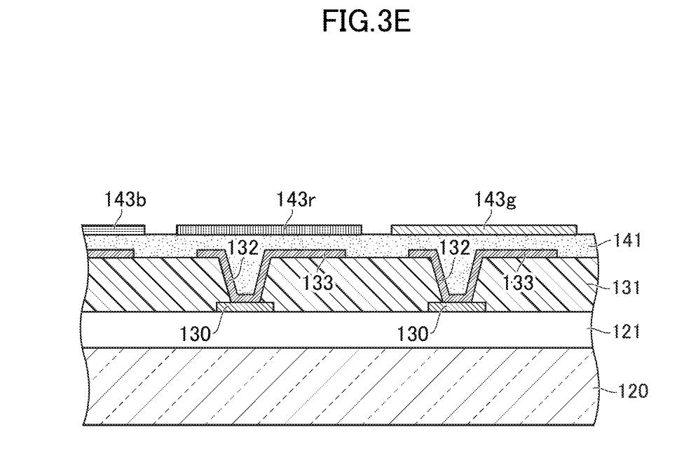

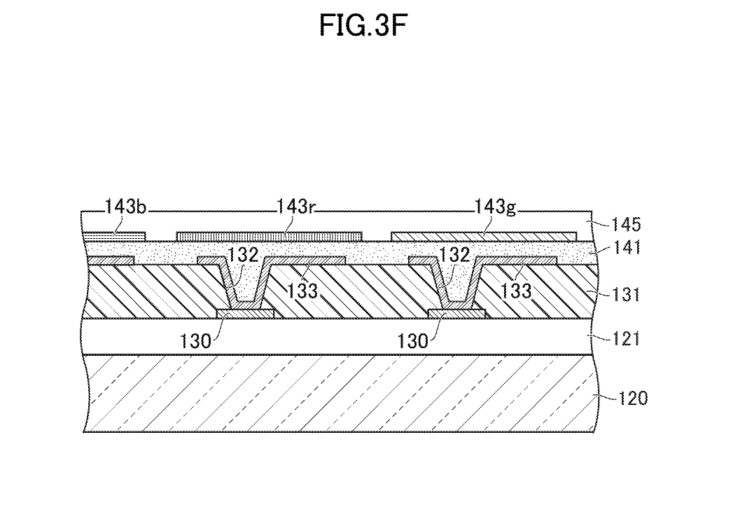

FIGS. 3A to 3F are diagrams illustrating a manufacturing process of the array substrate 120 illustrated in FIG. 2. Firstly, the circuit layer 121 is formed on the array substrate 120. More specifically, the following processes are performed. A semiconductor layer is formed by stacking and patterning a semiconductor. An insulating material containing silicon oxide or silicon nitride, for example, is stacked to form the under gate insulating layer. Stacking and patterning one or a plurality of metal layers are performed to form the first electrode layer, the insulating materials similar to the under gate insulating film are stacked to form the upper gate insulating layer, and the contact hole is formed on a position of the source and the drain in the semiconductor layer. Stacking and patterning one or a plurality of metal layers are performed to form the second electrode layer. The first electrode layer and the second electrode layer are formed by a metal layer selected from molybdenum (Mo), titanium (Ti), aluminum (Al), or the like, or a stacked layer thereof. In addition, by the process of forming the second electrode layer, the connection electrode 130 that is a part of the source or the drain electrode is also formed.

When the circuit layer 121 is formed, the interlayer insulating film 131 is formed by an organic insulating material, for example, and furthermore, the contact holes 132 are formed on the interlayer insulating film 131 so as to expose the connection electrode 130. The pixel electrode 133 is formed on the interlayer insulating film 131 and the contact holes 132 by stacking and patterning the electrode layer. The material of the pixel electrode 133 is determined in consideration of a work function for driving the organic EL element and is configured by an oxide conductive material or the like selected from indium tin oxide (ITO), indium zinc oxide (IZO), zinc oxide (ZnO), and the like. In addition, in a case of the top emission organic EL display, the pixel electrode 133 may be a reflection layer that reflects light and may have a layer of silver (Ag), Al, or the like.

After the pixel electrode 133 is formed, the hole injection/transport layer 141 (first organic layer) is formed by a coating type organic material (refer to FIG. 3A). At this time, the hole injection/transport layer 141 covers the upper surface and the side surface of the pixel electrode 133, and the hole injection/transport layer 141 is formed such that the lowest portion of the upper surface of the hole injection/transport layer 141 is higher than the highest portion of the pixel electrode 133 (refer to FIG. 3B). Furthermore, the material of the hole injection/transport layer 141 is coated in an amount sufficient for covering the irregular under the hole injection/transport layer 141 to make the irregular flat.

When the hole injection/transport layer 141 is formed, the coating type organic material for forming the light emitting film 143r is applied to the entire surface (refer to FIG. 3C). Since the upper surface of the hole injection/transport layer 141 is flat, the thickness of the applied coating type material is almost uniform regardless of a location. The applied coating type organic material is patterned by photolithography to form the red light emitting film 143r (refer to FIG. 3D). The green light emitting film 143g and the blue light emitting film 143b are also formed in the same process as the red light emitting film 143r (refer to FIG. 3E). When the electron injection/transport layer 145 (third organic layer) is stacked on the light emitting films 143r, 143g, and 143b by the coating type organic material (refer to FIG. 3F), and the common electrode 136 is stacked, as illustrated in FIG. 2. Here, the material of the common electrode 136 is determined in consideration of a work function and the like for driving the organic EL element and is configured by a transparent conductive material or the like selected from indium tin oxide (ITO), indium zinc oxide (IZO), zinc oxide (ZnO), and the like. When the configuration illustrated in FIG. 2 is obtained, the sealing film is formed on the upper layer with a resin, and the sealing film is bonded to the counter substrate 150.

As illustrated in FIG. 2, the irregular under the hole injection/transport layer 141 is covered with the hole injection/transport layer 141, and the upper surface of the hole injection/transport layer 141 is flattened. Accordingly, the thicknesses of the light emitting films 143r, 143g, and 143b stacked on the hole injection/transport layer 141 are uniform, and the luminance and the color unevenness inside the pixels 210 are suppressed. Among the light emitting films 143r, 143g, and 143b, since the hole injection/transport layer 141 in the contact holes 132 is thick, a portion overlapping with the contact holes 132 in plan view has a large resistance and the light emitting films 143r, 143g, and 143b do not emit the light. Only the light emitting films 143r, 143g, and 143b are patterned by photolithography, and the hole injection/transport layer 141 and the electron injection/transport layer 145 are not patterned. Accordingly, conditions relating to matching between a solvent used for etching and the electron injection/transport layer 145, the hole injection/transport layer 141, and the light emitting films 143r, 143g, and 143b are eased, and it becomes easy to select a light emitting material or the like with good characteristics.

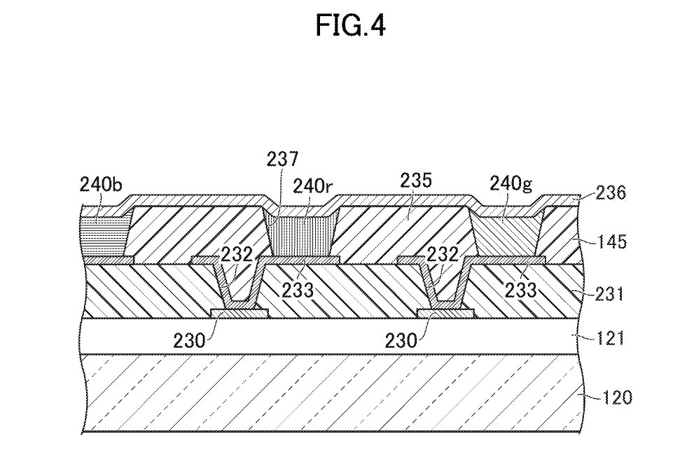

FIG. 4 is a cross-sectional view illustrating a comparison example of the array substrate 120. In FIG. 4, an interlayer insulating film 231 is formed on the circuit layer 121, a contact hole 232 is formed in the interlayer insulating film 231, and pixel electrodes 233 are also formed on the interlayer insulating film 231 and inside the contact hole 232. On the other hand, unlike the example of FIG. 2, the inside the contact hole 232 is filled with the insulating material of an insulating bank 235, and organic EL layers 240r, 240g, and 240b configuring the organic EL element are filled inside an opening 237 of the insulating bank 235. At the bottom of the opening 237, the pixel electrodes 233 are exposed from the insulating bank 235 and the pixel electrodes 233 are in contact with a connection electrode 230 at the bottom of the opening 237. In the same manner of the example of FIG. 2, the organic EL layers 240r, 240g, and 240b have a hole transport/injection layer, the light emitting layer, and en electron injection/transport layer. The upper surfaces of the organic EL layers 240r, 240g, and 240b are in contact with a common electrode 236.

In an comparison example of FIG. 4, in a case where the coating type organic EL material is filled, the upper surfaces of the organic EL layers 240r, 240g, and 240b become higher as the upper surfaces are closer to the side wall of the opening 237 of the insulating bank 235 due to the influence of surface tension and the like. As it will be understood from the above description, the thickness of the light emitting layer included in the organic EL layer becomes ununiform. Since the luminance and color hue of the organic EL element are affected by the thickness of the light emitting layer, the brightness and the wavelength change depending on the location, in a case where the thickness of the light emitting layer is ununiform. Accordingly, in a case of using the coating type light emitting material, for example, it is difficult to cause the organic EL element to emit light in an optimum state.

On the other hand, in the organic EL display device according to the present embodiment, the thicknesses of the light emitting films 143r, 143g, and 143b are uniform, changes in the luminance and the color hue are suppressed as compared with the example of FIG. 4. In addition, the size of the contact holes 132 is smaller than that of the opening 237 of the insulating bank 235 in FIG. 4, and the light emitting films 143r, 143g, and 143b do not emit light on the contact holes 132. Accordingly, even when a distance between the pixel electrode 133 and the light emitting films 143r, 143g, and 143b is changed in the region on the contact holes 132, the influence on the overall luminance and color hue is smaller than in the example of FIG. 4.

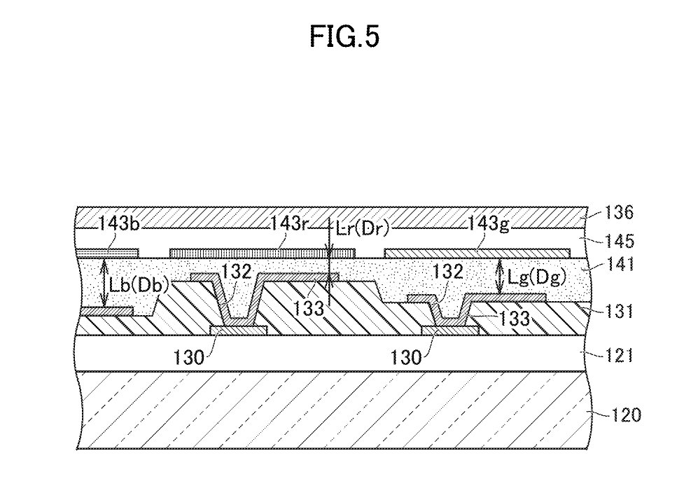

Here, a shape of the interlayer insulating film 131 and shapes of the light emitting films 143r, 143g, and 143b may be different from those in the example of FIG. 2. As a modification example, FIG. 5 is a cross-sectional view illustrating another example of the array substrate 120 according to the embodiment of the present invention and is a diagram corresponding to FIG. 2.

In the example of FIG. 5, each of the pixel electrodes 133 is a reflecting mirror that reflects light from the part of the light emitting films 143r, 143g, and 143b overlapping therewith in plan view. In addition, the thickness of the interlayer insulating film 131 is different between the region of the red pixel 210, the region of the green pixel 210, and the region of the blue pixel 210, and the height of the upper surface of the hole injection/transport layer 141 is the same. Accordingly, in each pixel 210, the thickness of the hole injection/transport layer 141 immediately under the light emitting films 143r, 143g, and 143b differs depending on the group of colors to which the pixels 210 belong. Accordingly, a distance Lr between the pixel electrode 133 and the light emitting film 143r in the red pixel 210, a distance Lg between the pixel electrode 133 and the light emitting film 143g in the green pixel 210, and a distance Lb between the pixel electrode 133 and the light emitting film 143b in the blue pixel 210 are different from each other. Accordingly, an optical path length Dr between the pixel electrode 133 and the light emitting film 143r in the red pixel 210, an optical path length Dg between the pixel electrode 133 and the light emitting film 143g in the green pixel 210, and an optical path length Db between the pixel electrode 133 and the light emitting film 143b in the blue pixel 210 are also different from each other. In addition, the optical path lengths Dr, Dg, and Db are adjusted according to the wavelength of the light emitting color such that optimum light emission (microcavity effect) is caused by superposition of the reflected light and direct light.

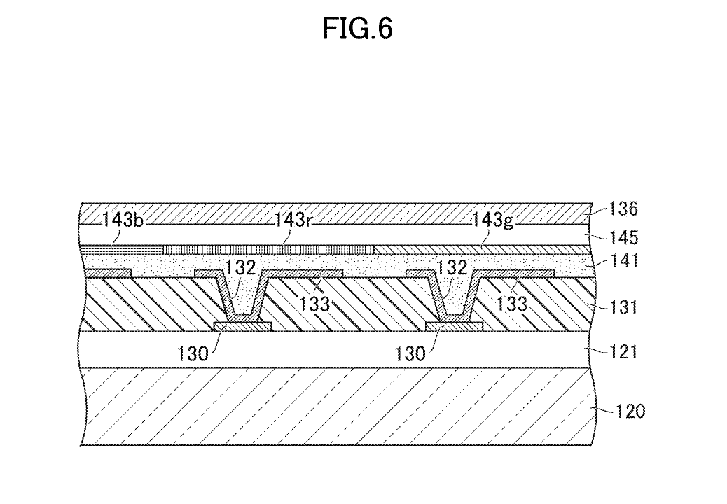

FIG. 6 is a cross-sectional view illustrating another example of the array substrate 120 according to the embodiment of the present invention, and a diagram corresponding to FIG. 2. Unlike the example of FIG. 2, in the example of FIG. 6, each of the light emitting films 143r, 143g, and 143b is not separated from the other light emitting films. Alternatively, the side surface of each of the light emitting films 143r, 143g, and 143b is in contact with the side surface of the adjacent light emitting films. Accordingly, the hole injection/transport layer 141 and the electron injection/transport layer 145 are prevented from directly contacting with each other, and current leakage due to the directly contacting can be prevented.

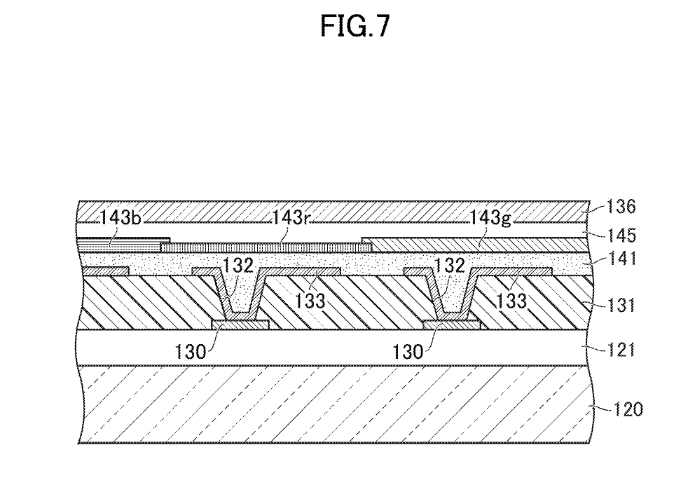

FIG. 7 is a cross-sectional view illustrating another example of the array substrate 120 according to the embodiment of the present invention and is a diagram corresponding to FIG. 2. In the example of FIG. 7, the end portion of each of the light emitting films 143r, 143g, and 143b overlaps with the end portion of the adjacent light emitting films vertically. In the same manner of the example of FIG. 6, each of the light emitting films 143r, 143g, and 143b is not separated from the other light emitting films, and the current leakage can be prevented. In addition, in the example of FIG. 7, the thickness of each of the light emitting films 143r, 143g, and 143b is determined according to the group to which the light emitting films belong. In other words, the light emitting film belonging to the different group among the light emitting films 143r, 143g, and 143b has difference thicknesses. Accordingly, the thicknesses of the light emitting films 143r, 143g, and 143b are optimized according to the emitting color. Also in the example of FIG. 2 or FIG. 5, the thicknesses of the light emitting films 143r, 143g, and 143b may be different from each other.

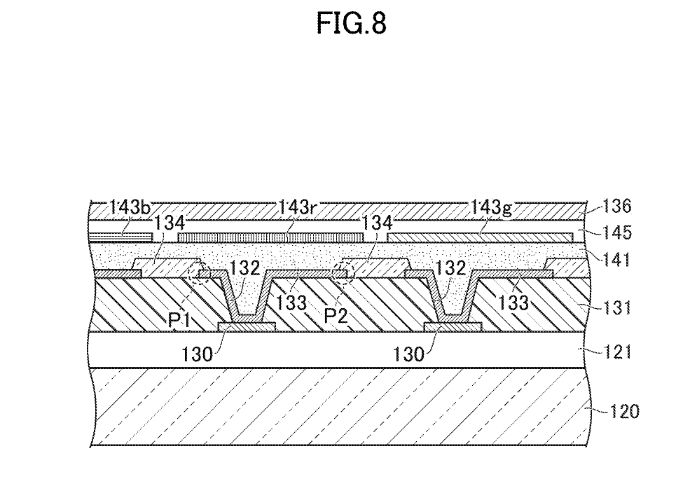

FIG. 8 is a cross-sectional view illustrating another example of the array substrate 120 according to the embodiment of the present invention and is a diagram corresponding to FIG. 2. In the example of FIG. 8, an inter-pixel insulating film 134 that covers both the adjacent end portions among the end portions of the plurality of pixel electrodes 133 adjacent to each other is formed. In other words, the end portion of the inter-pixel insulating film 134 in the horizontal direction in plan view covers end portions P1 and P2 of the pixel electrode 133. The inter-pixel insulating film 134 is formed of an inorganic insulating material such as silicon nitride or silicon oxide. The hole injection/transport layer 141 covers the inter-pixel insulating film 134, and the flat upper surface of the hole injection/transport layer 141 is higher than the upper end of the inter-pixel insulating film 134. In the example of FIG. 8, the end portions P1 and P2 of the pixel electrode 133 are not in contact with the hole injection/transport layer 141. Generally, although the electric field tends to concentrate on a corner at the upper portion of the end portions P1 and P2 of the pixel electrode 133, the configuration of FIG. 8 prevents a large current from flowing at the corner, and deterioration of the organic EL element can be prevented.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A display device comprising:
a plurality of pixel electrodes being apart from each other;
a carrier injection/transport layer stacked on the plurality of pixel electrodes across the plurality of pixel electrodes;
a plurality of light emitting layers positioned on an opposite side of the carrier injection/transport layer from the plurality of pixel electrodes, each of the plurality of light emitting layers being above each of the pixel electrodes;
a common electrode which covers the plurality of light emitting layers; and
underlayers which are in contact with the carrier injection/transport layer and are positioned on an opposite side of the carrier injection/transport layer from the light emitting layer,
wherein each of the plurality of pixel electrodes has an upper surface positioned at a side of the carrier injection/transport layer,
at least a part of the upper surface is a flat portion,
the underlayers include the plurality of pixel electrodes,
a first surface of the underlayer has an irregular shape, the first surface being in contact with the carrier injection/transport layer,
a second surface of the carrier injection/transport layer is flat, the second surface positioned at a side of the light emitting layer,
each of the light emitting layers faces the flat portion of each of the pixel electrodes, and
a thickness of each of the light emitting layers is uniform directly above the flat portion.

2. The display device according to claim 1,
wherein the underlayer further includes a first insulating film positioned on an opposite side of the plurality of pixel electrodes from the carrier injection/transport layer, and
the carrier injection/transport layer is in contact with the upper surface, side surfaces of the pixel electrodes, the side surfaces intersecting with the upper surface, and a surface of the first insulating film.

3. The display device according to claim 1,
wherein each of the pixel electrodes has a concave portion recessed toward an opposite side from the carrier injection/transport layer.

4. The display device according to claim 3,
wherein the carrier injection/transport layer fills the concave portion.

5. The display device according to claim 1,
wherein the plurality of light emitting layers are apart from each other.

6. The display device according to claim 1,
wherein the plurality of light emitting layers include a first light emitting layer and a second light emitting layer adjacent to the first light emitting layer, and
a side surface of the first light emitting layer is in contact with a side surface of the second light emitting layer.

7. The display device according to claim 1,
wherein the plurality of light emitting layers include a first light emitting layer and a second light emitting layer adjacent to the first light emitting layer, and
an end portion of the first light emitting layer has an overlap with an end portion of the second light emitting layer.

8. The display device according to claim 1
wherein the plurality of light emitting layers include a first light emitting layer emitting a first color and a second light emitting layer emitting a second color different from the first color.

9. The display device according to claim 8,
wherein a thickness of the first light emitting layer is different from a thickness of the second light emitting layer.

10. The display device according to claim 8,
wherein the carrier injection/transport layer has a first region facing the first light emitting layer and a second region facing the second light emitting layer, and
a thickness of the first region is different from a thickness of the second region.

11. The display device according to claim 1,
wherein the plurality of pixel electrodes include a first pixel electrode and a second pixel electrode adjacent to the first pixel electrode,
an area between the first pixel electrode and the second pixel electrode, a first end portion of the first electrode adjacent to the area, and a second end portion of the second electrode adjacent to the area are covered with a second insulating film,
the second insulating film is in contact with a portion of the upper surface of the first electrode and a portion of the upper surface of the second electrode, and
the carrier injection/transport layer covers an entirety of the second insulating film.

12. A display device comprising:
a substrate;
a circuit layer which is disposed on the substrate and includes at least a thin film transistor;
an insulating film disposed above the circuit layer;
a plurality of pixel electrodes positioned on the insulating film and disposed apart from each other;
a first organic layer which is positioned on the insulating film and covers an entirety of the plurality of pixel electrodes;
a plurality of second organic layers which are positioned on the first organic layer and have a light emitting film, each of the second organic layers facing each of the pixel electrodes, and
a common electrode which covers an entirety of the plurality of second organic layers.

13. The display device according to claim 12, further comprising:
a third organic layer covering an entirety of the plurality of second organic layers,
wherein the third organic layer is positioned between the plurality of second organic layers and the common electrode.

14. The display device according to claim 12,
wherein the first organic layer has a first surface which is in contact with the second organic layer,
the first surface has a first region overlapping with the plurality of pixel electrodes in a plan view and a second region overlapping with a portion between two of the plurality of pixel electrodes in the plan view,
the first surface has a flat portion located from the first region to the second region continuously.

15. The display device according to claim 14,
wherein the first organic layer includes a second surface which faces the first surface and positioned at a side of the plurality of pixel electrodes, and
the first surface is flatter than the second surface.

16. The display device according to claim 12,
wherein the plurality of second organic layers include two second organic layers adjacent to each other, and
a part of one of the two organic layers is in directly contact with a part of an other of the two organic layers.

17. The display device according to claim 12,
wherein the plurality of pixel electrodes include a first pixel electrode and a second pixel electrode adjacent to the first pixel electrode,
a second insulating film is disposed on the insulating film,
the second insulating film covers a first end portion of the first pixel electrode which is positioned at a side of the second pixel electrode, a second end portion of the second pixel electrode which is positioned at a side the first pixel electrode, and a boundary portion between the first end portion and the second end portion, and
the second insulating film is covered with the first organic layer.
